(19) United States
(12) Patent Application Publication
(10) Pub. No.: US 2006/0237730 A1
(43) Pub. Date: Oct. 26, 2006

(54) Peltier cooler with integrated electronic device(s)

(76) Inventor: Vladimir Abramov, (US)

Correspondence Address: Page Lohr Associates, P O Box 757, La Jolla, CA, 92038-0757, US

(21) Appl. No.: 10/545,216

(22) PCT Filed: Jan. 29, 2004
(86) PCT No.: PCT/IB04/00202

§ 371 Date: Aug. 4, 2005

Related U.S. Application Data
(63) Continuation of application No. 10/360,955, filed on Feb. 7, 2003, now abandoned.

(51) Int. Cl. H01L 33/00; H01L 35/34; H01L 35/28

(52) U.S. Cl. 257/81; 257/E23.082; 257/E27.12; 257/E33.075; 136/204; 136/201

(57) ABSTRACT

A Peltier effect cooling device is formed in combination with an electronic device to form a unique thermal and electrical relationship. An electronic device to be cooled is placed in a serial electrical relationship between at least two thermoelectric couples while simultaneously being in thermal contact with a cold side of the cooler arrangement. The same current which produces the thermoelectric effect in the Peltier thermocouples also drives the electronic device. A balanced effect results as a higher driving current through the electronic device to causes greater heating, it is offset by the added cooling due to a greater current in the thermocouples. In addition, a unique spatial arrangement provides improved heat distribution and transfer to a heat sink. Due to the unique shapes of Peltier elements, heat is pulled radially from a heat generating source and distributed at a peripheral region. Shaped Peltier elements are tapered from a small cold area to a large hot area to further magnify the transfer of heat.

The field of these inventions includes semiconductor electronics and specifically semiconductors used to promote the Peltier effect for cooling of electronic components.

Peltier coolers and the use of them to cool electronic elements and devices is well known. However, typical arrangements of these include a plurality of thermal couples in contact with two planar elements. Thus, there is a ‘hot’ plane and a ‘cold’ plane spatially removed there from. This system is invariably used in all Peltier configurations. In addition, the Peltier cooler and the device to be cooled are typically electrically isolated. That is, they are thermally coupled but are on different electronic circuits. The current passed through the Peltier cooler is not related to the current passed through the cooled device.

While the systems and inventions of the art are designed to achieve particular goals and objectives, these concepts have limitations which prevent their use in new ways now possible. These art inventions of the art are not used and cannot be used to realize the advantages and objectives of the present invention.

Comes now, Abramov, V.; Agafonov, D.; Scherbakov, N.; Shishov, A.; Sushkov, V.; Drabkin, I.; and Marychev, V. with inventions of Peltier cooling systems integrated with a common electronic device or devices and further having spatial arrangement to facilitate heat dispersion.

Peltier cooling systems are arranged with specially shaped thermocouples. These semiconductor elements appropriately doped to effect Peltier cooling/heating functions are also shaped to transmit heat away from a heat source in a radial direction to a peripheral region. In this way, a large area heat dump more effectively cools the small area of the heat generating device. Additionally, some versions also remove heat from a small area region in a cooling plane to separate plane displaced there from. Still further, some versions incorporate a special electronic arrangement whereby the cooling system and cooled system share a single electronic circuit. That is to say, the Peltier elements may be driven by the very same current as the cooled electronic device. A serial electronic circuit permits a single current to drive the electronic device and provide cooling effect.

In a best version, an LED is placed between each thermocouple of a multiple couple system. Thus a light emitting diode array is formed to produce high output while the current is routed through a series of alternately doped Peltier elements to effect cooling. This configuration further benefits from a multiplying factor which is possible as a result of a radial arrangement which permits a Peltier ‘hot’ side which is much larger in area than the Peltier ‘cold’ side.

It is a primary object of these inventions to provide improved arrangements of Peltier cooling devices.

It is additionally an object of these inventions to provide Peltier devices which operate directly and integrally in conjunction with their heat load.

It is a further object to provide a balanced cooling effect with respect to demand.

A better understanding can be had with reference to detailed description of preferred embodiments and with reference to appended drawings. Embodiments presented are particular ways to realize the invention and are not inclusive of all ways possible. Therefore, there may exist embodiments that do not deviate from the spirit and scope of this disclosure as set forth by the claims, but do not appear here as specific examples. It will be appreciated that a great plurality of alternative versions are possible.

These and other features, aspects, and advantages of the present invent ion will become better understood with regard to the following description, appended claims and drawings where:

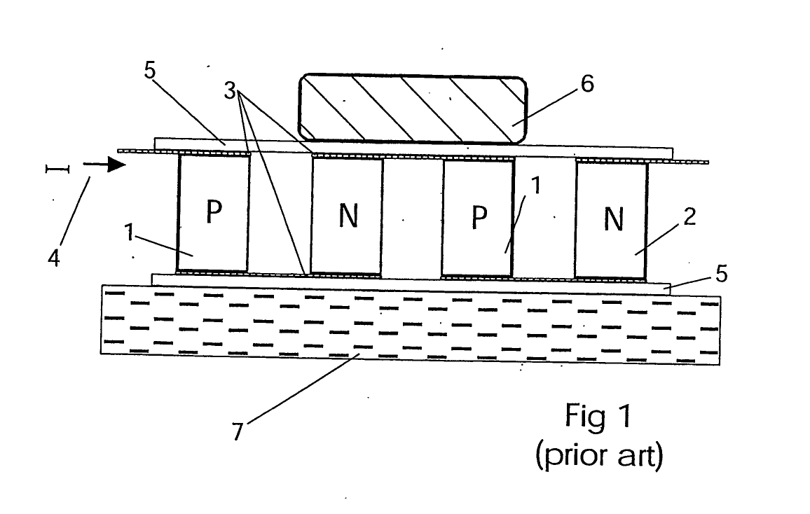

FIG. 1 is a prior art diagram of a common Peltier cooler and its heat load;

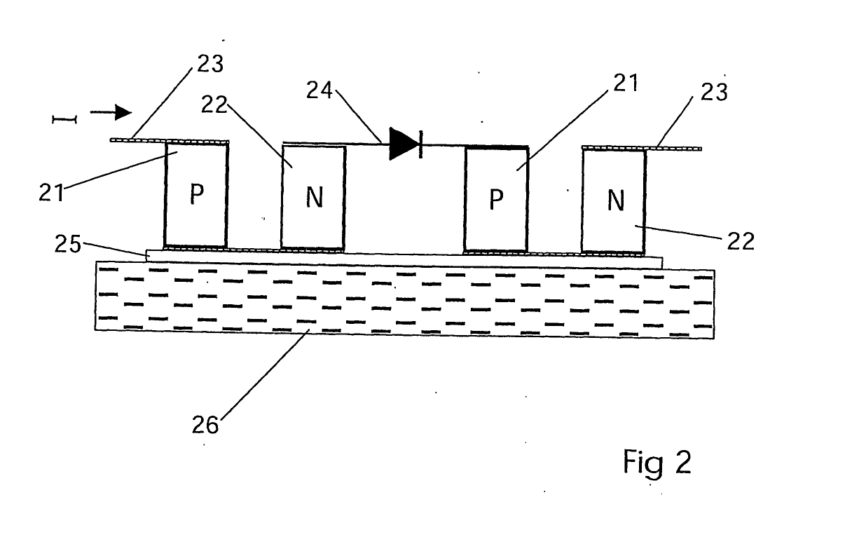

FIG. 2 illustrates a special first version of these inventions;

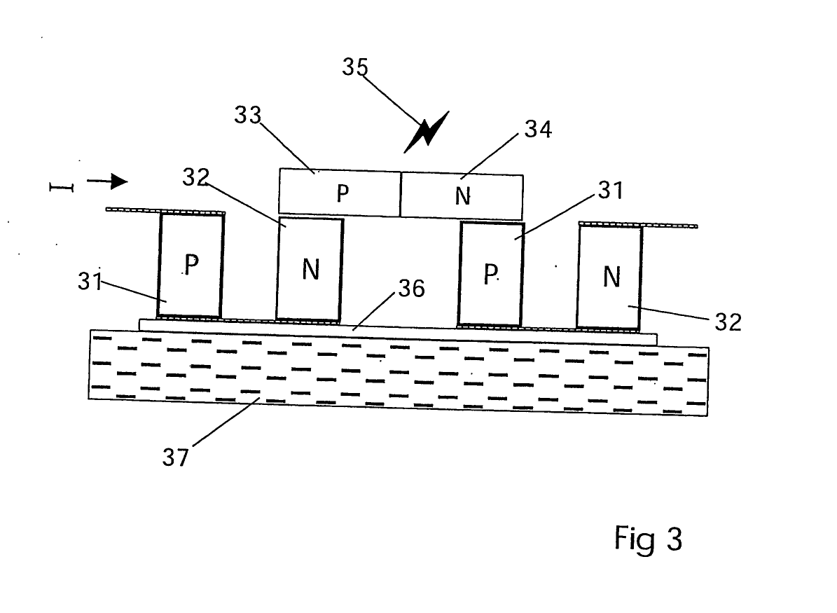

FIG. 3 presents a more detailed description of the same or similar version;

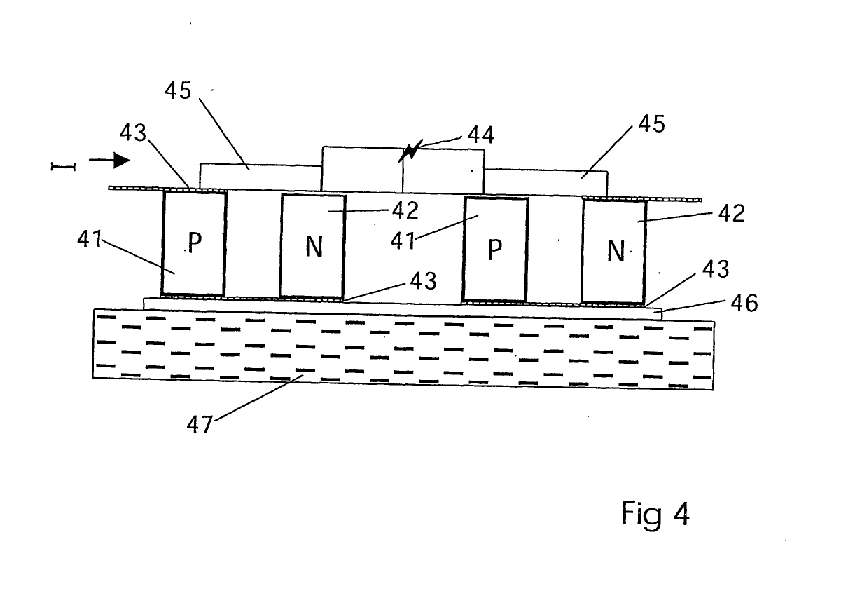

FIG. 4 shows additionally detail as to parallel heat coupling;

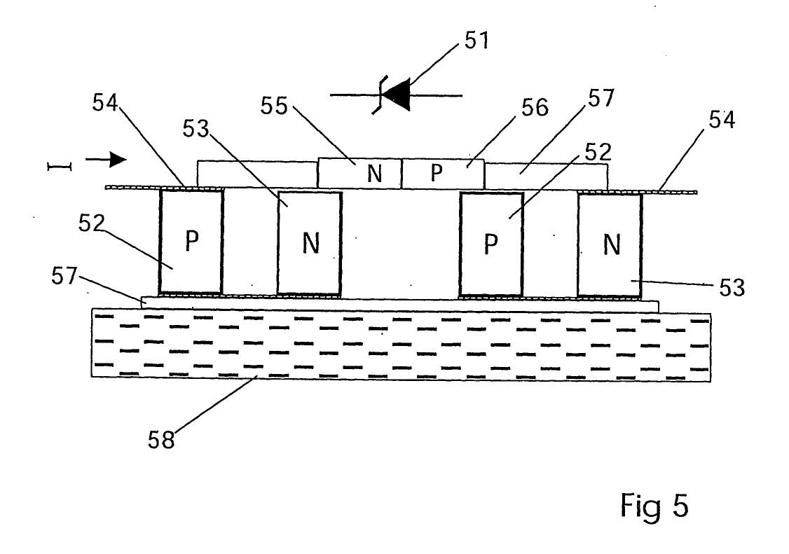

FIG. 5 shows in block diagram a reversed biased arrangement which also works with these inventions;

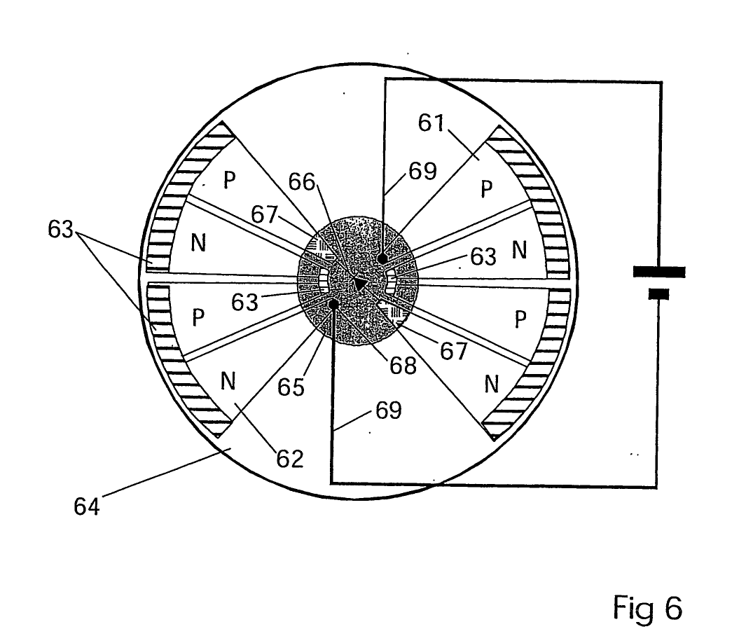

FIG. 6 is a top-down view of special arrangements of preferred shaped Peltier elements arranged in serial with a diode device;

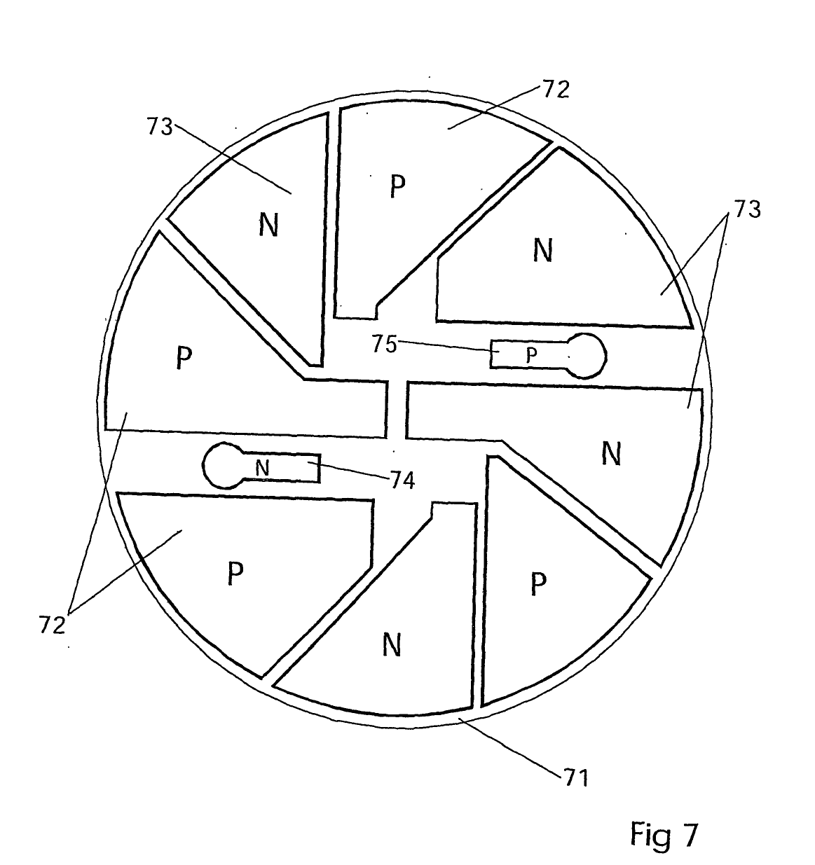

FIG. 7 illustrates an alternative version having specially shaped Peltier elements to support a radially distributed configuration;

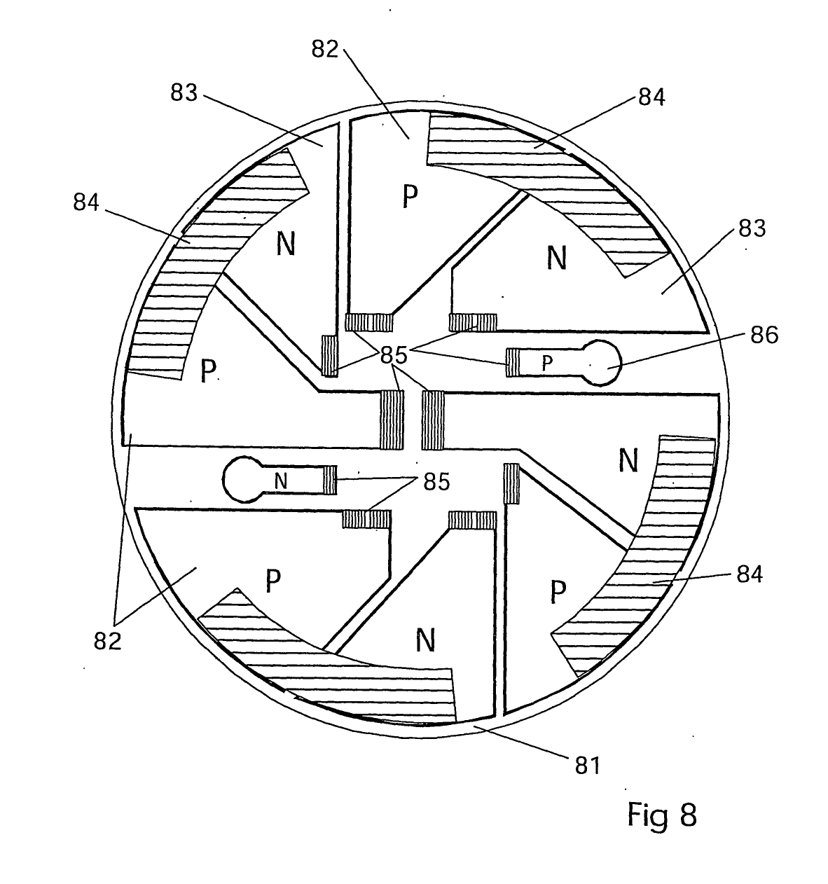

FIG. 8 illustrates the connection aspects of this preferred version;

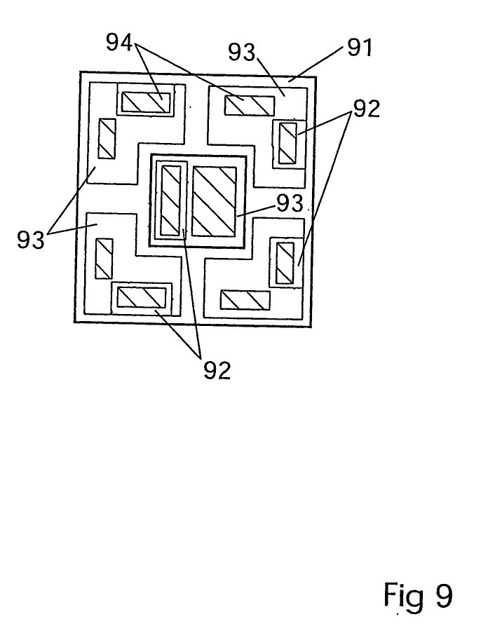

FIG. 9 is a diagram of a ‘flip-chip’ component arranged to cooperate with the design of the previous figures;

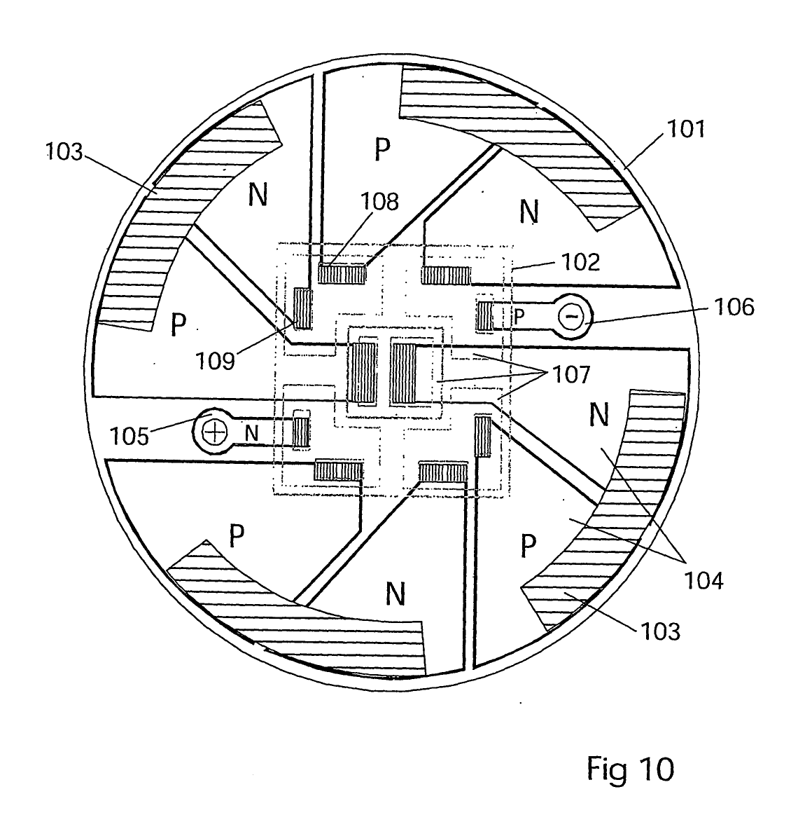

FIG. 10 shows an apparatus having distributed Peltier elements and the flip chip in contact proximity therewith to form a serial electric circuit;

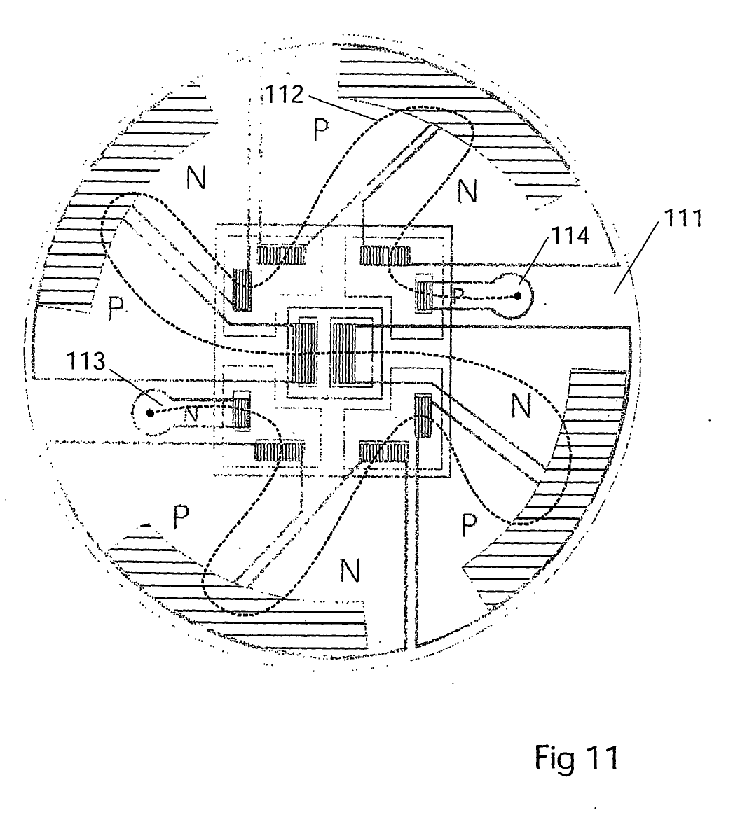

FIG. 11 includes a special illustration of current path;

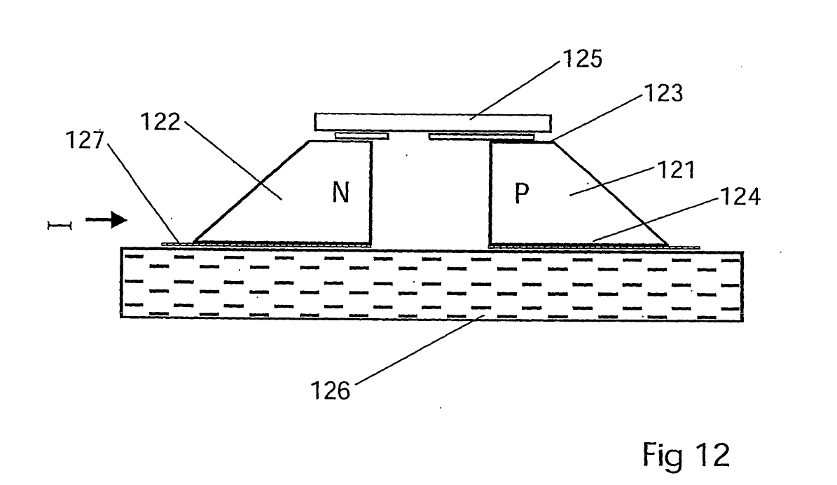

FIG. 12 is a sectional diagram to show special three dimensionally shaped Peltier elements; and

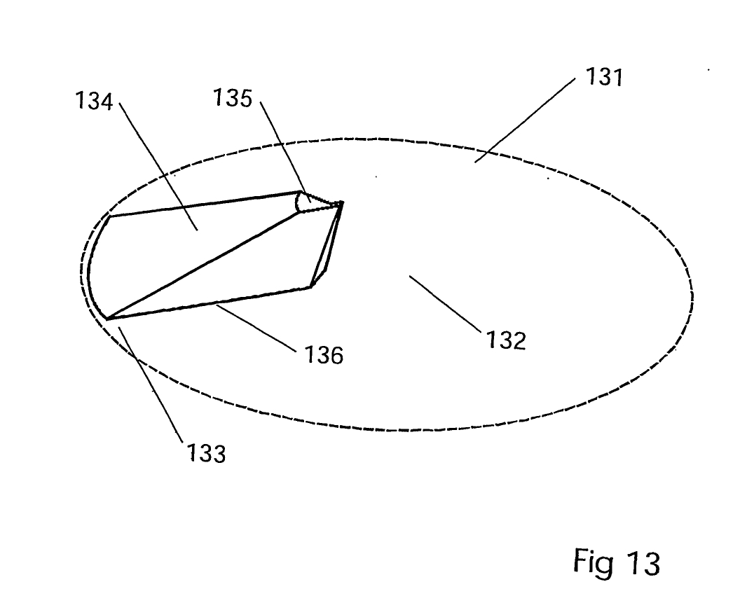

FIG. 13 presents a perspective view of a version having a shaped Peltier element in three dimensions.

In accordance with each of preferred embodiments of the invention, a Peltier cooler integrated with electronic device or devices is provided. It will be appreciated that each of the embodiments described include both an apparatus and that the apparatus of one preferred embodiment may be different than the apparatus of another embodiment.

With reference to the drawing figures one will gain a more complete appreciation of these inventions. FIG. 1 illustrate a common Peltier cooler and in conjunction with a heat load. The device is primarily made of Peltier elements of ‘P’-type semiconductor material 1 and Peltier elements of ‘N’-type semiconductor material 2. These two semiconductor types are arranged in a spatially alternating fashion. The permits convenient electrical contact between elements. Each element has a ‘hot side’ and a ‘cold side’ in view of a predetermined current direction. For example, the current shown 4 in the Figure causes the top side for both ‘P’ and ‘N’ type materials to be the cooled side. Because the electrical circuit formed by way of metal conductors 3, one will appreciate the current flow through ‘P’-type material is in the opposite direction as through ‘N’-type elements. It is sometimes said that the Peltier elements are arranged electrically in a serial fashion while being thermally coupled in a parallel fashion. Ceramic thermal conductor 5 assures that heat may be transferred about the top of each of the Peltier elements. Similarly, a ceramic element may thermally couple the bottoms of the Peltier elements such that they are also in a parallel thermal arrangement with respect to each other. A thermal load 6, is the ‘cooled member’, i.e. the device for which it is desired to be cooled or temperature controlled. A heat sink 7 is a device which operates to receive heat and sometimes to pass heat into a surrounding environment sometimes via a convection process.

Conductors 3 are interlaced between Peltier elements and form an electrical contact there between them. The metal-semiconductor junction forms the necessary physical conditions which yield the Peltier effect. However, there is nothing particularly important about the conductor which lies between any two elements other than it must make contact therewith. It is not important whether or not a voltage drop occurs before the conductor makes contact with the following Peltier element. For this reason, a conductor may be replaced with an electronic device. Indeed, an electronic device which operates on the same current as that which passes through the Peltier elements may also be the heat load to be cooled. Consider the case where a metallic conductor is replaced by a diode electronic element.

FIG. 2 illustrates a first version of these inventions where a conductor has been replaced with a diode electronic device to form a series circuit with several Peltier elements. ‘P’-type Peltier elements 21 and ‘N’-type Peltier elements 22 form an alternating arrangement. Current I is introduced in conductors 23 to form a series circuit through these elements. In addition, diode 24 is electrically connected in series with respect to two of the Peltier elements and replaces a conductor. At the ‘hot side’, ceramic thermal conductor 25 and heat sink 26 remain in arrangements without modification from common configurations. Current forced through the cooling member is necessarily the same current forced through the cooled member, i.e. the diode.

A more detailed drawing shows how a certain diode, formed of semiconductor materials, may be placed in series electrical contact with a Peltier cooling member. In FIG. 3, a cooling member is comprised of Peltier cooling elements of the ‘P’-type 31 and Peltier elements of the ‘N’-type 32. A special light emitting diode is comprised of ‘P’/‘N’ pair 33 and 34. This diode is of the type which emits light 35 upon simulation from a forward bias current of sufficient strength. In this type of diode, the light emitted is proportional to the amount of current driven through the device. A light emitting diode is presented here to illustrate that it is not important precisely which kind of electrical element replaced the conductor, but that various types of electronic devices might be placed in the circuit. Finally, in the conventional way, the bottoms of the Peltier elements are thermally coupled via ceramic slab 36 which is further in thermal communication with heat sink 37. A careful observer may be quick to note trouble with the proposed arrangement of FIG. 3. Indeed, a serious shortcoming exists there. When removing the ceramic slab of thermal conductor to make way for the electrical device, the thermal coupling between two of the top elements (the exterior elements) has been also removed. Although the top of those elements continue to become cold in response to current passing through the device, they no longer collect heat from the cooled device, i.e. the light emitting diode. To remedy this, a special thermal coupling is arranged and detailed in FIG. 4.

Similar to the previous example, a cooling member is formed of alternating ‘P’-type 41 and ‘N’-type 42 semiconductor elements tied together to form a serial electronic circuit via conductors 43 and cooled member LED 44. A thermal connection between the tops of all Peltier elements is formed via thermal conductors 45 which draw heat from the LED and pass it to the top of the exterior Peltier element s. It is important to note that these members while being highly conductive in the thermal sense, they are necessarily electrical insulators. Some ceramic materials can be used for such purposes. They may be formed in various ways compatible with the formation of electrical device process and are made from materials easily worked in conjunction therewith. As such, the ‘cold side’ of each Peltier element is coupled to the others and connected electrically in serial. It will be appreciated that the diagram is merely a schematic and that the precise geometry of an actual device can take many forms which will not look like the drawing figure. At the ‘hot side’, a thermal pad 46 couples the bottom side of the Peltier elements to a heat sink 47.

FIG. 5 illustrates yet another type of electrical device, a Zener diode 51, i.e. a diode operated in reverse bias. Peltier elements 52 and 53 are arranged as shown and electrically connected by current carrying conductor 54. The Zener diode has ‘N’-type 55 and ‘P’-type 56 semiconductor material arranged in the reverse direction but similarly coupled to the Peltier elements at the center of the arrangement. Thermal pads 57 couple either the tops of the bottoms of the Peltier elements to the cooled member and the heat sink respectively. Again, this illustration proposes the notion that various arrangements of elements may be constructed to operate in a serial electrical connection with specially formed Peltier devices.

As presented previously, another significant part of these inventions relates to the different sizes of the cooled member and the heat dissipation means or heat sink. Although common Peltier devices generally have a cold side of similar size and shape as the hot side, devices of these inventions support a very unique arrangement of Peltier elements which allows the ‘hot side’ to be far larger in area than the ‘cold side’. This further promotes the notion of dispersing heat in an efficient manner. This may be realized via shaped Peltier elements. Indeed non-rectangular shaped elements support these arrangements quite well. The Peltier elements of the art are always rectangular or rectangular cylinders. Where three dimensional arrangements are presented in these inventions, non cylindrically shaped Peltier elements are suggested.

With reference to FIG. 6, one will fully appreciate the advantage of the unique arrangement of Peltier elements having a non-rectangular shape. ‘P’-type Peltier elements 61 are formed in pie wedge shapes extending from a center region outwardly toward a disk periphery. Similarly, non-rectangular ‘N’-type Peltier elements 62 are formed to take a similar shape. The ‘hot side’ of the elements corresponds to the disk periphery. Conductors 63 electrically couple each of the Peltier elements to the one next to it to form a serial relationship between then whereby current first passes through one then the other. One with notice conductors also at the ‘cold side’ of the Peltier elements also arranged to couple a ‘P’-type Peltier element to an ‘N’-type Peltier element in a serial electronic circuit. With judicious application of imagination, one can appreciate that disk 64 is a heat sink which lies at the bottom of a stack of elements extending outward from the plane of the drawing figure page. The Peltier elements lie on the top of the heat sink and may be thermally coupled thereto. In some versions, only the periphery of the disk has a strong thermal coupling to the Peltier elements. In the drawing, this is reflected in the fact that the semiconductor-metal junction is shaped as a section of a ring far from the disk center. The center of the disk 65 may be an electronic element. It is draw here by example as a diode symbol 66 to illustrate the electrical connection, but it is understood that the actual device has physical extent an may occupy significant area in the drawing. Although the area designated by disk 65 most clearly illustrates the diode device, actual preferred versions may include diodes having a rectangular shape. This does not affect the geometry of the drawing nor the operation of the device in an appreciable way. For clarity, the area 65 is presented as the cooled member, for example a diode. The cooled member can be fabricated atop the Peltier elements, indeed the stack of layers which form the entire device such that the cooled member area is well coupled thermally to each of the cold side of the Peltier elements by proximity and contact. In addition, the electrical contacts of the cooled member, or diode in this example, can be arranged to complete the serial electrical circuit by way of the Peltier elements. Special electrical connections 67 indicate where electrical contact is made between the cooled member and the certain Peltier elements. Other Peltier elements are electrically connected at points 68 to an electric drive circuit which supplies current to the entire apparatus. Note that connection points 68 are electrically isolated from the diode via an insulative layer not shown; the diode is only connected electrically to the points indicated as 67.

One can carefully follows a current path from the battery symbol through each element of the device and that exercise is done here. From the positive terminal of the battery current flows into the first Peltier element at a metal-‘P’-type semiconductor junction to cause a cooling effect. Current leaves that first Peltier element at a ‘P’-type semiconductor-metal junction and causes heating there at the periphery of the assembly.

That heat may be passed to a radiative heat sink. Current flows through the metal conductor to the adjacent Peltier element which is an ‘N’-type semiconductor. Electrical current is forced through another metal semiconductor junction, however this time it is of the opposite type, an metal-‘N’-type junction. Electrical activity there is effectively the positive charge carriers, or so called ‘holes’ transferring heat energy to that junction. This heat energy was collected and transferred from the narrowest part of that same ‘N’ element at yet another metal-semiconductor junction. The current flows through another ‘P’ element, and another ‘N’ element, at each junction causing cooling and heating respectively. Finally, the current is injected into the diode device. In the diode junction, activity such as light emission may be stimulated. As mentioned, it is not necessary that the device be a diode but may be a complex electronic device such as a specialty transistor or other electronic device. After passing through the electronic device, the current is again introduced into the chain of Peltier elements, first ‘P’-type, then ‘N’-type, et cetera. Finally the current finds a return path back to the current source.

It is additionally useful to mention the flow of thermal energy in more detail. Heat generated at the electronic device may be extensive. That heat is drawn to the cold portions of the Peltier elements, i.e. the tip of each pie wedge piece which is in good thermal contact with the electronic device; in this example, the diode. That heat is quickly dispersed radially by charge carriers, both electrons and holes, and transferred to the heat sink at specially arranged metal-semiconductor junctions at the device periphery. In this way, a high performance electronic device which tends to be limited by overheating conditions, may operate at far high operation parameters than in the case where heat tends to build at the device.

The example presented in FIG. 6 comprises particular symmetry and is drawn for clarity and understanding without regard for efficiency. One will appreciate that alternative geometries will have improved functionality and would be preferred in actual devices. A best mode version of these inventions includes that which is presented in FIGS. 7-10. In this version, asymmetric arrangements of Peltier elements are arranged in a fashion to pull heat radially from a central location towards a disk perimeter. It is noted that the disk perimeter is comprised of far greater area than the central region as is necessarily the case with disk type geometries. Also, the following examples illustrate the very special cases where a plurality of electronic elements are integrated with the Peltier device elements. In this case, an array of light emitting diodes is arranged in a serial circuit with alternating Peltier elements.

FIG. 7 illustrates a particular arrangement of ‘N’ and ‘P’ type semiconductor Peltier elements. These elements may be formed on a disk substrate such as a silicon wafer in conventional processes used in forming semiconductor materials. The precise two dimensional shape shown is merely a good candidate for useful devices contemplated here. It will be surely appreciated that other similar configurations exist which will bring about the same effect without deviation from the spirit of this teaching. The thickness of the semiconductor material may be uniform over the entire surface of the disk. In this regard, these configurations are sometimes referred to as ‘two dimensional’. Where the thickness of the Peltier elements varies as a function of distance in a direction orthonormal from the wafer plane, those configurations are called ‘three dimensional’.

A wafer substrate upon which semiconductor materials may be fabricated forms a base in the shape of a disk 71. While silicon wafers are a common material from which the base of a semiconductor manufacture process is started, it is explicitly stated here that other materials may offer competing advantages. In either case, semiconductor material doped in a fashion whereby the crystal has a deficiency of electrons, i.e. is left with ‘hole’-type carriers, forms ‘P’ type Peltier elements 72. Similarly, semiconductor material doped to result in a crystal having excess electrons, or negatively charged carriers, forms ‘N’ type Peltier elements 73. In some preferred embodiments, Bi2Te3 based materials are used to form thermocouples; i.e. both ‘P’ and ‘N’ type Peltier elements. SiGe and SiGeC compounds have also been used to form interesting combinations.

Special ‘N’ type element 74 and special ‘P’ type element 75 are provided in this scheme to provide contact means and a balance of pairs or ‘couples’ as they are sometimes and herein referred. These specially shaped elements may be coupled with metallic leads to provide electrical lead interface access to the entire device.

To more completely understand the entire device, one must focus attention on the nature of the electronic circuit formed by the device elements. Specifically, the Peltier elements must form a serial electric circuit. Accordingly, special connectors are arranged to electrically couple ‘P’ type elements to the ‘N’ type elements at the peripheral edge of the disk. Attention is directed to FIG. 8 and the reference numerals therein. The same Peltier elements of FIG. 7 are constructed on a wafer 81 where ‘P’ type 82 and ‘N’ type 83 material elements are alternating such that neighbours on either side are comprised of the opposite material type. Special metallic connectors 84 form electrical contact between Peltier couples. The metallic connectors form a critical part of the Peltier action. Current going from ‘P’ type material into a metallic conductor causes heating. Similarly, current going from the metallic conductor into ‘N’ type materials also causes heating. The opposite action, i.e. cooling, occurs where current passes from ‘N’ type and into ‘P’ type. Therefore special connection pads 85 are provided at the Peltier elements are the disk center region. To these connection pads, one may provide a metallic conductor to bridge two pads thus forming a connection with the other adjacent opposite material type. In the alternative, one may place into the electric circuit some discrete electronic component such as an light emitting diode. The two leads of a diode may be connected between the ‘N’ and ‘p’ Peltier elements. In fact, a diode without metallic leads but rather the semiconductor material from which the diode is comprised may be affixed to the pads 85. In this case, the ‘p’ portion of the diode is connected to the ‘N’ type Peltier element and the ‘N’ portion of the diode is connected to the ‘p’ type Peltier element. In the present example, there are five pairs of pads to which LEDs may be coupled. Thus, to complete a serial electronic circuit in this version, five LEDs are affixed to the contact points 85.

To more readily understand this arrangement consider the LED array presented as FIG. 9. Using so called ‘flip chip’ technology, a five unit semiconductor array of LED devices are formed on a single substrate. A wafer 91 of silicon, silicon-carbon, or alternative material may support a structure upon which an array of diodes may be formed. By way of processes such as chemical vapor deposition, molecular beam epitaxi, or other, material is grown to form a diode ‘P-N’ junction. In some diodes, this is done with materials such as InGaN. Material doped to form ‘N’ type portions 92, and material doped to form ‘P’ type portions 93 are the essence of the diode structure. Careful inspection of the diagram suggests an alley between each discrete diode and indeed it is intended that electrical isolation exists therebetween each of the five diodes. A special contact pad 94 is formed and deposited in contact with each ‘n’ type and ‘p’ type diode portion. These pads may be formed of AuSn, gold-tin, or alternative conductor appropriate for bump or other type conventional bonding process. Where a chip is formed in the configuration described, it may be combined with the prepared Peltier device described previously. FIG. 10 illustrates a diode array combined with a specially arranged Peltier system.

A ‘flip chip’ diode array formed in accordance with prescribed geometries. In addition, a multi-element Peltier cooler is formed with shaped Peltier elements, each Peltier element having a first end small in area located centrally with respect to a disk further having a second end disposed at the periphery of same disk. These two elements are combined and pressed together whereby contact pads cause electrical contact between diode elements and Peltier elements to form a perfect electronic series circuit. With reference to drawing FIG. 10, the entire device is included within the geometry of disk perimeter 101. Flip chip 102 comprises an array of five individual LED elements arranged in a predetermined geometry. Connectors 103 between Peltier element-pairs 104 lie at the disk periphery and cover substantial area there. The complete circuit has two terminal ends or poles a ‘positive’ 105 and a ‘negative’ 106. To these leads, one may apply a potential to cause electrical current to flow through all of the elements of the combination including each of the diodes 107. A close look will reveal that each diode is coupled to two Peltier elements, one of ‘P’ type and one of ‘N’ type, at connection pads 108 and 109 respectively.

While the drawing has many elements thus making it difficult to visualize a current path, the drawing of FIG. 11 provides aid in this regard. FIG. 11 illustrates the combination device 111 with a current path drawn in dashed line 112 for illustration purposes. From positive terminal 113, current flows first through an ‘N’ type Peltier element, then a first LED, a ‘P’ type Peltier element, a peripheral connector, an ‘N’ type Peltier element, a second LED, another ‘P’ type Peltier element, another peripheral connector, an ‘N’ type Peltier element, the center diode, a ‘P’ type Peltier element, a peripheral connector, an ‘N’ type element, a diode, another Peltier couple, a fifth diode and finally to a ‘P’ type Peltier element tied to a negative pole or device terminal lead. Experts in the theory of Peltier device operation will verify that at peripheral connection heating occurs, and at each interior connection cooling action occurs. Heat generated at the LEDs is thus carried from the center of the disk to the disk periphery by way of currents in the Peltier elements. The same current which activates the Peltier cooling action is used to drive the diode devices as the circuit is formed alternately of diodes and Peltier couples.

Where common Peltier cooling systems have a ‘hot side’ and a ‘cold side’, these devices do not. Rather, these devices have specialized geometries to support heat migration in a radial direction away from heat generating source or sources. The geometries of known Peltier elements include only rectilinear Peltier elements and thus they cannot account for the cooling action described here. Further those devices operate with two separate electronic circuits one for the cooling systems and one for the device being cooled; typically an electronic discrete device. The currents are not shared between these isolated systems in the art. Thus the ‘hot side’ of these very special Peltier coolers is not a side at all, but rather, is the periphery of a disk.

Although the detailed examples presented above with reference to drawing FIGS. 7-10 are explicit and complete, it is interesting to note yet another version of significant importance. It is further possible to expand the shaped Peltier element concept to ‘three dimensional’ elements. While the thin elements or ‘two dimensional’ elements of FIG. 6 are technically cylindrical having a non-rectilinear cross section, Peltier elements may also be formed as non-cylindrical elements. Drawing FIGS. 12 and 13 illustrate these special Peltier elements. In FIG. 12, a sectional slice shows shaped Peltier elements of non cylindrical symmetry. A first ‘P’ type element 121 is paired with ‘N’ type Peltier element 122 to form a cooling couple. Both of these Peltier elements are formed with a taper in the radial direction as shown. From an orthogonal point-of-view, i.e. a top-down view, the element may additionally have a pie wedge shape such as the elements described in FIG. 6. As apparent from the figure, the top surface 123 of both Peltier elements is smaller than the bottom surface 124. The heat generating element, i.e. an LED 125, is cooled via the apparatus because heat is drawn away from the ‘cold side’ downwardly toward the ‘hot side’ heat sink 126. One will appreciate that heat is not only drawn downwardly, but also drawn radially from the center in agreement with the principles taught first here. Further, the configuration also illustrate a diode placed in a series circuit with the cooling system. Electrical conductor 127 supports current flow to and from the Peltier elements while the only path connection those elements is through the diode 125.

These non-cylindrical, non-rectilinear shaped Peltier elements may be more clearly described in consideration of the perspective drawing of FIG. 13 which shows a single Peltier element in isolation in proximity to the apparatus disk 131. The disk includes a central region 132 and a peripheral region 133. The top of the Peltier element 134, either ‘P’ or ‘N’ type, is the ‘cold side’ 135. The bottom side is the ‘hot side’ 136. the tapered shape of the Peltier element assures that heat is not only drawn radially away from the center but also away from the top plane and toward the bottom plane of the device. Thus, these devices, like their predecessors, have a ‘hot side’ and a ‘cold side’ but additionally incorporate heat removal in a radial fashion as well. Further, they may also be designed to include the heat generating element, the heat load, in the same electrical circuit with the Peltier elements. The examples above are directed to specific embodiments which illustrate preferred versions of devices and methods of the invention. In the interests of completeness, a more general description of devices and the elements of which they are comprised as well as methods and the steps of which they are comprised is presented here following.

In most general terms, apparatus of the se inventions may be described as electronic apparatus having a cooling member coupled to a cooled member. The cooling member having several semiconductor elements configured to yield a Peltier effect. These semiconductor elements have a non-rectilinear or rectangular shape so as to yield a fanout, radially distributed arrangement. As such, the semiconductor elements have two ends. One is positioned centrally, and another is positioned peripherally. The central ends are smaller in size than said peripheral ends. Thus the Peltier semiconductor elements are arranged to extend radially from a central region to a peripheral region. In this way, cooling occurs at the central region, while heating occurs in the peripheral region. The central region is thermally coupled to at least one electronic device, for example a light emitting diode. In some cases, ‘the electronic device’ may be an array of diodes. Some versions have Peltier elements with extent in the depth dimension; i.e. they are shaped to displace the heating plane away from the cooling plane.

Peltier elements may be electrically connected with the electronic device to form a serial electronic circuit. This may be arranged such that Peltier elements lie on either side of the electronic device. Where the device is a diode, it may be either in the forward bias condition or the reversed bias condition.

Peltier elements may be connected to one another via metallic electrical conductors preferably shaped in annular sections.

One will now fully appreciate how a Peltier electronic cooler may be formed integrally with an electronic device such as a diode. Although the present invention has been described in considerable detail with clear and concise language and with reference to certain preferred versions thereof including the best mode anticipated by the inventor, other versions are possible. Therefore, the spirit and scope of the invention should not be limited by the description of the preferred versions contained therein, but rather by the claims appended hereto.

1) Electronic apparatus comprising a cooling member thermally coupled to a cooled member, said cooling member comprising a plurality of semiconductor elements configured to yield a Peltier effect when current is passed therethrough, the semiconductor elements having a non-rectilinear shape.

2) Electronic apparatus of claim 1, each of said semiconductor elements comprising two ends, a first end disposed centrally, and a second end disposed peripherally with respect to the entire arrangement of elements.

3) Electronic apparatus of claim 1, said first end being smaller in size than said second end.

4) Electronic apparatus of claim 3, said semiconductor elements being arranged to extend radially from a central region to a peripheral region.

5) Electronic apparatus of claim 4, said first ends of the semiconductor elements being arranged to cause a Peltier cooling function, said second ends of the semiconductor elements arranged to cause a Peltier heating function.

6) Electronic apparatus of claim 5, whereby said cooling occurs at said central region, said heating occurs at said peripheral region.

7) Electronic apparatus of claim 6, said central region is thermally coupled to at least one electronic device.

8) Electronic apparatus of claim 7, said at least one electronic device is a diode.

9) Electronic apparatus of claim 8, said at least one electronic device is a light emitting diode.

10) Electronic apparatus of claim 7, said at least one electronic device is an array of light emitting diodes.

11) Electronic apparatus of claim 4, said peripheral region is further coupled to a heat sink.

12) Electronic apparatus of claim 1, said semiconductor elements further having an asymmetry in a third spatial dimension to form a shaped fanout element.

13) Electronic apparatus of claim 12, said shaped fanout element has a cooled region and a heated region associated therewith, the cooled region is in a substantially different plane that the heated region.

14) Electronic apparatus comprising a cooling member thermally coupled to a cooled member, said cooling member comprising a plurality of semiconductor elements configured to yield a Peltier effect when current is passed therethrough, said cooled member is arranged to form a serial electronic circuit with said cooling member semiconductor elements.

15) Electronic apparatus of claim 14, said plurality of semiconductor elements include ‘P’-type doped semiconductor material and ‘N’-type doped semiconductor material disposed alternately, one adjacent to the other.

16) Electronic apparatus of claim 15, a least two of the semiconductor elements are electrically connected to said cooled member forming a series electronic circuit.

17) Electronic apparatus of claim 16, said semiconductor elements lie on either side of said cooled member with respect to the serial electronic circuit formed by the combination.

18) Electronic apparatus of claim 17, said semiconductor elements have a ‘hot side’ and a ‘cold side’ in accordance with the Peltier effect.

19) Electronic apparatus of claim 18, said ‘cold side’ being coupled to said cooled member.

20) Electronic apparatus of claim 19, said cooled member is an electronic device in a forward biased electrical arrangement.

21) Electronic apparatus of claim 19, said cooled member is an electronic device in a reversed biased electrical arrangement.

22) Electronic apparatus of claim 20, said cooled member is at least one diode device.

23) Electronic apparatus of claim 22, said cooled member is at least one light emitting diode.

24) Electronic apparatus of claim 23, said cooled member is an array of light emitting diodes.

25) Electronic apparatus of claim 15, semiconductor elements are non-rectangular.

26) Electronic apparatus of claim 25, semiconductor elements form a radial fanout.

27) Electronic apparatus of claim 26, semiconductor elements have connectors therebetween semiconductor pairs to form thermoelectric couples in accordance with the Peltier effect.

28) Electronic apparatus of claim 27, said connectors are characterized as annular sections of metallic material affixed to one ‘P’ type Peltier element and one ‘N’ type element.

29) Electronic apparatus of claim 28, said at least one light emitting diode includes one light emitting diode per thermoelectric couple.

30) Electronic apparatus of claim 29, said first ends comprise a plurality of spatially distributed bond pads operable for receiving thereon and forming a bond therewith a ‘flip chip’ electronic device.

31) Electronic apparatus of claim 25, semiconductor elements are non-cylindrical to form a non-symmetric structure in three spatial dimensions.

32) Electronic apparatus comprising a cooling member thermally coupled to cooled member, said cooling member comprising a plurality of semiconductor elements configured to yield a Peltier effect when current is passed therethrough, the semiconductor elements having a non-rectangular shape, said cooled member being an electronic device arranged and electrically coupled to form a series electronic circuit with the semiconductor elements of the cooling member.

33) Electronic apparatus of claim 32, said semiconductor elements are formed whereby Peltier cooling occurs in a central region and Peltier heating occurs at a peripheral region with the semiconductor elements extending radially therebetween those two regions.

34) Electronic apparatus of claim 33, the semiconductor elements are characterized as being substantially wedge shaped, a pointed or narrow end supporting Peltier cooling, a broad opposite end supporting Peltier heating.
